(19) United States
(12) Patent Application Publication
(10) Pub. No.: US 2017/0018673 A1
(43) Pub. Date: Jan. 19, 2017

(54) URANIUM OXIDE SOLAR CELLS

(71) Applicant: Los Alamos National Security, LLC, Los Alamos, NM (US)

(72) Inventors: Igor Usov, Los Alamos, NM (US); Milan Sykora, Los Alamos, NM (US)

(73) Assignee: Los Alamos National Security, LLC, Los Alamos, NM (US)

(21) Appl. No.: 15/188,152

(22) Filed: Jun. 21, 2016

Related U.S. Application Data
(60) Provisional application No. 62/191,601, filed on Jul. 13, 2015.

(51) Int. Cl. H01L 31/068; H01L 31/18; H01L 31/0445; H01L 31/032; H01L 31/0224

(52) U.S. Cl. CPC H01L 31/068; H01L 31/0321; H01L 31/022466; H01L 31/0445; H01L 31/18

(57) ABSTRACT

Solar cells including thin film depleted uranium oxide (DUO) may be produced using an ion beam assisted deposition (IBAD) process, for example. p-type DUO film and n-type DUO film may form a p/n junction. The photovoltaic (PV) structure may be completed by evaporating a metal electrode on top of one of the DUO films.

### CROSS REFERENCE TO RELATED APPLICATION

This application claims the benefit of U.S. Provisional Application Ser. No. 62/191,601 filed Jul. 13, 2015. The subject matter of this earlier filed application is hereby incorporated by reference in its entirety.

### STATEMENT OF FEDERAL RIGHTS

The United States government has rights in this invention pursuant to Contract No. DE-AC52-06NA25396 between the United States Department of Energy and Los Alamos National Security, LLC for the operation of Los Alamos National Laboratory.

### FIELD

The present invention generally relates to solar cells, and more specifically, to depleted uranium oxide solar cells and processes for their production.

### BACKGROUND

Depleted uranium oxide (DUO) is an abundant and cheap waste byproduct of the nuclear fuel enrichment process. As used herein, DUO refers to molecules including uranium and oxygen of the form UₓO_{y}, where x=1-3 and y=1-8. DUO is currently produced at a rate of approximately 30,000 tons per year at several de-conversion facilities. The current practical uses of DUO are limited.

Employment of depleted uranium oxide (e.g., UO₂—also known as uranium dioxide) in a solar cell device was proposed for the first time in 2000 by R. R. Price for depleted uranium waste utilization. See R. R. Price, M. J. Haire, and A. G. Croff, “Potential Uses of Depleted Uranium,” International Winter and Embedded Topical Meetings, Washington D.C. (Nov. 12-16, 2000). Electrical and optical properties of bulk polycrystalline and single crystalline UO₂ were investigated, but no depleted UO₂ solar cell has been reported.

### SUMMARY

Certain embodiments of the present invention may provide solutions to the problems and needs in the art that have not yet been fully identified, appreciated, or solved by conventional solar cell technologies. For example, some embodiments of the present invention pertain to solar cells including thin film DUO and processes for their production.

In an embodiment, an apparatus includes an n-type material placed adjacent to or affixed to a p-type material, forming a p/n junction. At least one of the p-type material and the n-type material comprises DUO.

In another embodiment, a DUO solar cell includes a p-type DUO film and an n-type DUO film positioned so as to form a p/n junction between the p-type DUO film and the n-type DUO film. The n-type DUO film is deposited on a transparent conductive substrate.

In yet another embodiment, an apparatus includes a transparent electrode and a p-type DUO film deposited on the transparent electrode. The apparatus also includes an n-type DUO film deposited on the p-type DUO film and a metal electrode deposited on the n-type DUO film.

### BRIEF DESCRIPTION OF THE DRAWINGS

In order that the advantages of certain embodiments of the invention will be readily understood, a more particular description of the invention briefly described above will be rendered by reference to specific embodiments that are illustrated in the appended drawings. While it should be understood that these drawings depict only typical embodiments of the invention and are not therefore to be considered to be limiting of its scope, the invention will be described and explained with additional specificity and detail through the use of the accompanying drawings, in which:

FIG. 1 is a side view illustrating a DUO solar cell, according to an embodiment of the present invention.

FIG. 2 is a schematic diagram illustrating an ion beam assisted deposition (IBAD) setup and images, according to an embodiment of the present invention.

### DETAILED DESCRIPTION OF THE EMBODIMENTS

Some embodiments of the present invention pertain to solar cells including thin film DUO and processes for their production. Electronic and optical properties make DUOs excellent candidates for exploitation in photovoltaics (PVs). The band gap of UO₂, the most studied DUO form, is at ˜1.3 electron volts (eV), which is comparable to silicon (Si) and gallium arsenide (GaAs), near the optimum for use of solar radiation. The UO₂ band gap can also be fine-tuned by adjustments in the oxygen content. Further, the absorption coefficient of DUO is orders of magnitude larger than that of Si and GaAs. The intrinsic conductivity of UO₂ at room temperature is similar to crystalline Si, and the purity of the stockpile DUO is comparable with semiconductor grade single crystal Si.

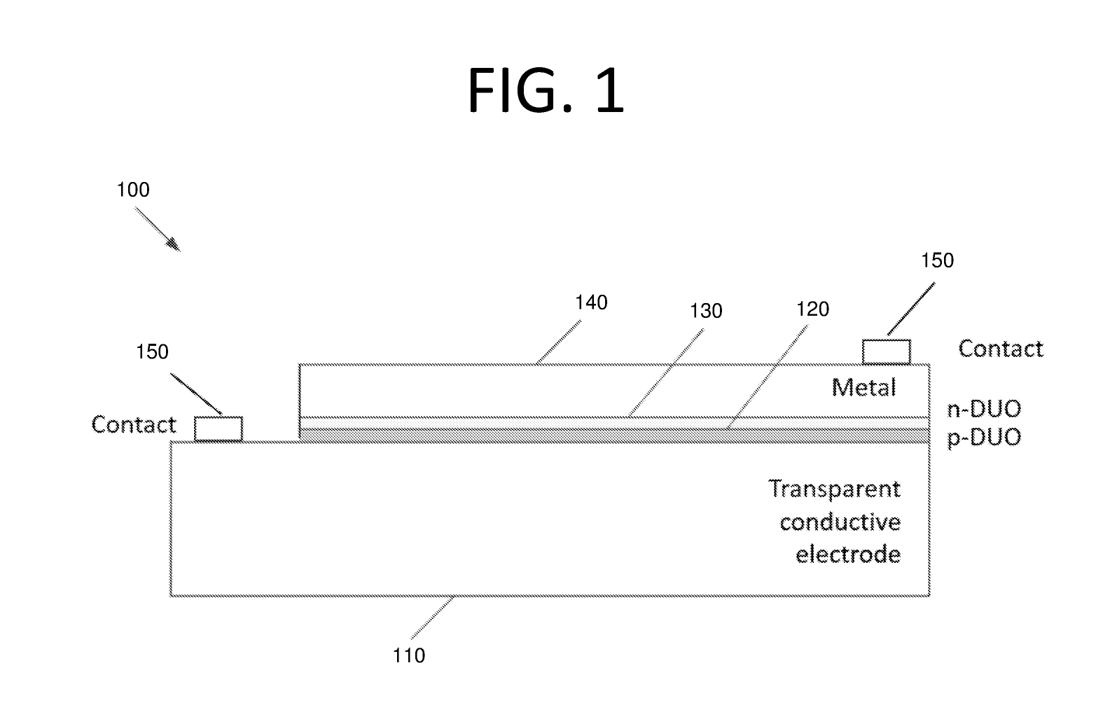

FIG. 1 is a side view illustrating a DUO solar cell 100, according to an embodiment of the present invention. DUO solar cell 100 includes a transparent conductive electrode 110 (e.g., tin-doped indium oxide (ITO), fluorine-doped tin oxide (FTO), etc.), a p-type DUO film 120, an n-type DUO film 130, and a metal electrode 140 (e.g., aluminum (Al), silver (Ag), gold (Au), or any other suitable metal for photovoltaic cell contacts). p-type DUO film 120 and n-type DUO film 130 may have thicknesses of a few nanometers to a millimeter and metal electrode 140 may have a thickness of a few nanometers to a few hundred nanometers in some embodiments. To form DUO solar cell 100, p-type DUO film 120 is deposited on transparent conductive electrode 110, and n-type DUO film 130 is deposited on p-type DUO film 120, forming a p/n junction therebetween. The generation of electric current happens when electrons from n-type DUO film 130 diffuse into the “holes” of p-type DUO film 120. Both n-type DUO film 130 and p-type DUO film 120 include DUO in this embodiment. However, in some embodiments, only n-type film 130 or p-type film 120 may include DUO.

When a photon of light is absorbed by one of the atoms in n-type DUO film 130, it dislodges an electron, creating a free electron and a hole. If a wire is connected from the cathode (i.e., n-type film 130) to the anode (i.e., p-type DUO film 120), electrons will flow through the wire. The electrons are attracted to the positive charge of p-type DUO film 120 and create a flow of electric current. As shown, DUO solar cell 100 includes electrical contacts 150.

Preparation of p-type and n-type DUOs to create p-type DUO film 120 and n-type DUO film 130 may be achieved by control of the oxygen-to-uranium (O/U) ratio and/or by doping with one or more group III elements (boron (B), aluminum (Al), gallium (Ga), indium (In), thallium (Tl), scandium (Sc), yttrium (Y), the lanthanides, and actinides), one or more group V elements (nitrogen (N), phosphorus (P), arsenic (As), antimony (Sb), bismuth (Bi), vanadium (V), niobium (Nb), tantalum (Ta), and dubnium (Db)), or any combination thereof. The doping may be achieved by employing standard co-evaporation or co-sputtering processes in some embodiments. UOs with metal deficiency are p-type semiconductors and UOs with metal excess are n-type semiconductors. A metal deficiency occurs when the material contains a smaller number of positive ions than negative ions due to cation vacancies and/or extra anions occupying interstitial sites. A metal excess occurs when the material contains a larger number of positive ions than negative ions due to anionic vacancies and/or extra cations occupying interstitial sites.

A new method for fabrication of DUO thin films on various substrates has been developed using an ion beam assisted deposition (IBAD) process, which provides exquisite control over stoichiometry (O/U ratio), microstructure, and thickness of DUO films by adjusting the deposition conditions. This advance allows some embodiments to address the deficiencies of previous approaches and develop DUO PVs. In addition, other applications of DUO, such as radiation-resistant electronics, may also be achieved.

O/U ratio may be controlled by changing the partial oxygen pressure during the film deposition in the IBAD process. The film microstructure can be controlled by the deposition temperature and post growth annealing. This allows tuning of the material band gap as manifested by the changes in the film color. Films with large and well oriented grains, demonstrating single crystal-like microstructure, can be produced even on non-epitaxial substrates, such as silicon carbide (SiC). Preparation of p-type and n-type DUOs may be achieved by control of the O/U ratio (UOs with metal deficiency are p-type semiconductors and UOs with metal excess are n-type semiconductors) and/or by doping with III and/or V group elements, as discussed above.

The IBAD setup may be readily modified in some embodiments to produce p-type and n-type films via doping. For instance, aluminum (Al) dopants can be introduced into the DUO matrix by co-sputtering of an Al target with energetic ions, such as xe⁺ or any other suitable energetic ion. The concentration of Al in the DUO matrix may be controlled by the ratio of DUO/Al deposition rates, which may be precisely adjusted. The solar cell development may be organized into three focus areas.

### Optimization of Duo Film Fabrication

The IBAD approach may be optimized for DUO film deposition with controlled thickness, U/O ratio, crystallinity, and doping. The film structure, O/U ratio, and dopant content may be characterized by standard analytical techniques.

### Fabrication and Characterization of Dou Solar Cell

p-type and n-type DUO films may be deposited on a transparent electrode using IBAD or other deposition processes. The PV structure may be completed by a metal electrode evaporated on top of the DUO film.

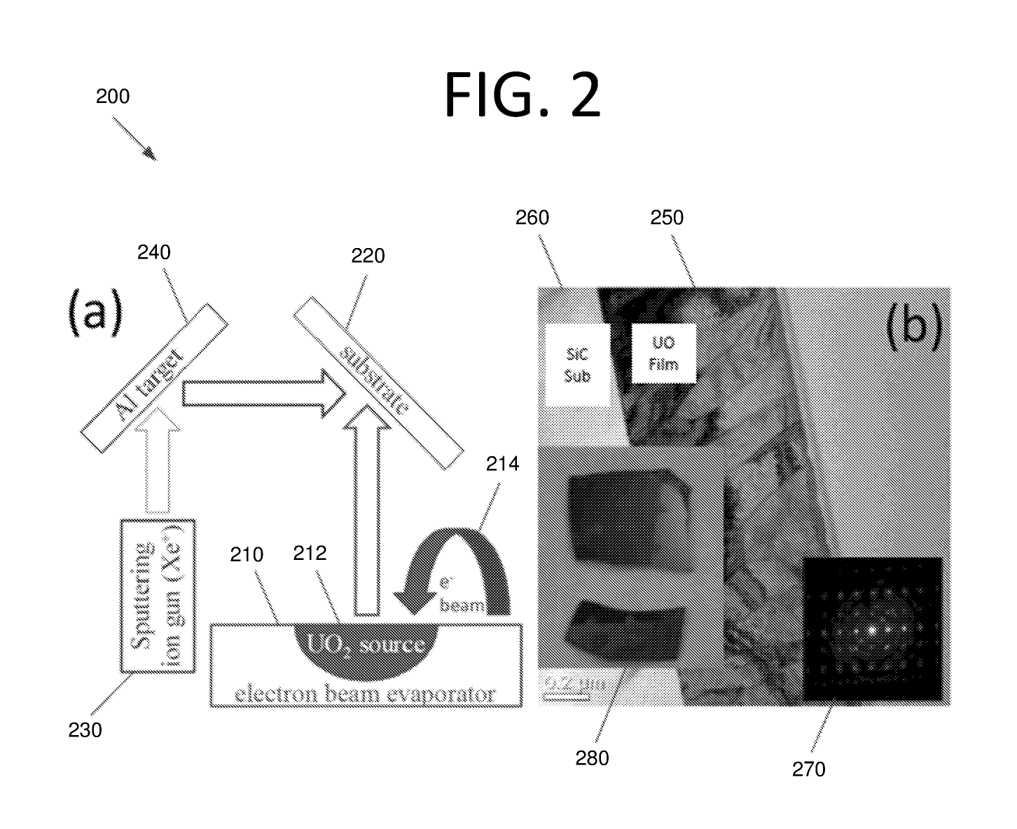

FIG. 2 is a schematic diagram illustrating an IBAD setup and images 200, according to an embodiment of the present invention. In (a), an electron beam evaporator 210 evaporates a DUO source (here, UO₂ source 212) when an electron beam 214 is applied, providing DUO to a substrate 220. A sputtering Xe+ ion gun 230 (or any other suitable energetic ion) sputters an Al target 240 (or other dopant per the above) to allow preparation of n-doped and p-doped thin films. In (b), a cross section of a DUO film 250 deposited on a surface of a SiC substrate 260 is shown. A diffraction pattern 270 of the film indicates crystallinity. A photograph 280 of two DUO films with different O/U ratios shows band-gap tunability.

It will be readily understood that the components of various embodiments of the present invention, as generally described and illustrated in the figures herein, may be arranged and designed in a wide variety of different configurations. Thus, the detailed description of the embodiments of the systems, apparatuses, methods, and computer programs of the present invention, as represented in the attached figures, is not intended to limit the scope of the invention as claimed, but is merely representative of selected embodiments of the invention.

The features, structures, or characteristics of the invention described throughout this specification may be combined in any suitable manner in one or more embodiments. For example, reference throughout this specification to “certain embodiments,” “some embodiments,” or similar language means that a particular feature, structure, or characteristic described in connection with the embodiment is included in at least one embodiment of the present invention. Thus, appearances of the phrases “in certain embodiments,” “in some embodiment,” “in other embodiments,” or similar language throughout this specification do not necessarily all refer to the same group of embodiments and the described features, structures, or characteristics may be combined in any suitable manner in one or more embodiments.

It should be noted that reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention can be practiced without one or more of the specific features or advantages of a particular embodiment. In other instances, additional features and advantages may be recognized in certain embodiments that may not be present in all embodiments of the invention.

One having ordinary skill in the art will readily understand that the invention as discussed above may be practiced with steps in a different order, and/or with hardware elements in configurations which are different than those which are disclosed. Therefore, although the invention has been described based upon these preferred embodiments, it would be apparent to those of skill in the art that certain modifications, variations, and alternative constructions would be apparent, while remaining within the spirit and scope of the invention. In order to determine the metes and bounds of the invention, therefore, reference should be made to the appended claims.

1. An apparatus, comprising:
an n-type material placed adjacent to or affixed to a p-type material, forming a p/n junction, wherein at least one of the p-type material and the n-type material comprises depleted uranium oxide (DUO).

2. The apparatus of claim 1, wherein the n-type material and the p-type material are sufficiently thin to allow light to pass through to the p/n junction between the p-type material and the n-type material.

3. The apparatus of claim 1, wherein the p-type material comprises an oxygen-to-uranium (O/U) ratio that causes a metal deficiency.

4. The apparatus of claim 1, wherein the n-type material comprises an oxygen-to-uranium (O/U) ratio that causes a metal excess.

5. The apparatus of claim 1, wherein the p-type material, the n-type material, or both, comprise uranium dioxide (UO₂).

6. The apparatus of claim 1, wherein p-type material, the n-type material, or both, are doped with one or more group III elements, one or more group V elements, or any combination thereof.

7. The apparatus of claim 1, further comprising:
a transparent conductive electrode positioned on one side of the p/n junction; and
a metal electrode positioned on another side of the p/n junction.

8. The apparatus of claim 7, wherein
the p-type material comprises a p-type DUO film and the n-type DUO material comprises an n-type DUO film, and
the p-type DUO film is deposited on the transparent conductive electrode.

9. The apparatus of claim 8, wherein
the n-type DUO film is deposited on the p-type DUO film, and
the metal electrode is deposited on the n-type DUO film.

10. A depleted uranium oxide (DUO) solar cell, comprising:
a p-type DUO film; and
an n-type DUO film positioned so as to form a p/n junction between the p-type DUO film and the n-type DUO film, wherein
the n-type DUO film is deposited on a transparent conductive substrate.

11. The DUO solar cell of claim 10, wherein the p-type DUO film comprises an oxygen-to-uranium (O/U) ratio that causes a metal deficiency.

12. The DUO solar cell of claim 10, wherein the n-type DUO film comprises an oxygen-to-uranium (O/U) ratio that causes a metal excess.

13. The DUO solar cell of claim 10, wherein the p-type DUO film, the n-type DUO film, or both, comprise uranium dioxide (UO₂).

14. The DUO solar cell of claim 10, wherein p-type DUO film, the n-type DUO film, or both, are doped with one or more group III elements, one or more group V elements, or any combination thereof.

15. An apparatus, comprising:
a transparent electrode;
a p-type depleted uranium oxide (DUO) film deposited on the transparent electrode;
an n-type DUO film deposited on the p-type DUO film; and
a metal electrode deposited on the n-type DUO film.

16. The apparatus of claim 15, wherein the n-type DUO film and the p-type DUO film are sufficiently thin to allow light to pass through to the p/n junction between the p-type material and the n-type material.

17. The apparatus of claim 15, wherein the p-type DUO film comprises an oxygen-to-uranium (O/U) ratio that causes a metal deficiency.

18. The apparatus of claim 15, wherein the n-type DUO film comprises an oxygen-to-uranium (O/U) ratio that causes a metal excess.

19. The apparatus of claim 15, wherein the p-type DUO film, the n-type DUO film, or both, comprise uranium dioxide (UO₂).

20. The apparatus of claim 15, wherein p-type DUO film, the n-type DUO film, or both, are doped with one or more group III elements, one or more group V elements, or any combination thereof.
